(19) United States
(12) Patent Application Publication
(10) Pub. No.: US 2005/0266641 A1
(43) Pub. Date: Dec. 1, 2005

(54) Method of forming films in a trench

(75) Inventors: Shih-Chi Lai, Hsinchu (TW); Tun-Fu Hung, Hsinchu (TW); Yi-Fu Chung, Hsinchu (TW); Jen-Chieh Chang, Hsinchu (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: MOSEL VITELIC, INC., Hsinchu (TW)

(21) Appl. No.: 10/961,575

(22) Filed: Oct. 8, 2004

(30) Foreign Application Priority Data
May 31, 2004 (TW) 093115545

(51) Int. Cl. H01L 21/336

(52) U.S. Cl. 438/270; 438/272

(57) ABSTRACT

A method of forming films in a trench is applied to the manufacturing process of a power MOS device. In one embodiment, the method comprises providing a semiconductor substrate, forming a trench in the semiconductor substrate, forming a first dielectric layer on sidewalls of the trench, forming a second dielectric layer on the first dielectric layer, and forming a polysilicon layer in the trench. The method of forming films in a trench of the present invention can reduce or eliminate the thermal stress resulting from the different thermal expansion coefficients of different material layers after high temperature process.

### CROSS-REFERENCES TO RELATED APPLICATIONS

This application claims priority from R.O.C. Patent Application No. 093115545, filed May 31, 2004, the entire disclosure of which is incorporated herein by reference.

### BACKGROUND OF THE INVENTION

The present invention relates to a method of forming films in a trench, and more particularly to a method of forming films in a trench for a trench-typed power MOS device.

The trench and the technique of forming films in the trench are broadly used in the manufacturing processes of the power MOS devices and the MEMS devices. The technique of forming films in the trench is mainly to form plural material layers in the trench in turn with different materials. In the process of forming films in the trench, the stress will be produced due to the differences of the physical properties between different material layers. For example, the thermal expansion coefficients of the semiconductor substrate, the oxide layer, and the polysilicon layer of the trench-typed power MOS device are different. When a wafer is cooled down to the room temperature after a high temperature process, the compressive or tensile stresses will be produced due to different thermal expansion coefficients between each of the material layers, so that the wafer may be seamed, warped and bowed due to the thermal stress influence.

Therefore, it is desirable to develop a new method of forming films in the trench to overcome the aforesaid problems or difficulties, particularly for use in the manufacture of the trench-typed power MOS device. The technique of the present invention will prevent the wafer from being seamed, warped, or bowed due to the thermal stress influence.

### BRIEF SUMMARY OF THE INVENTION

Embodiments of the present invention provide a method of forming films in the trench to reduce or eliminate the thermal stress influence resulted from the different thermal expansion coefficients between each of the material layers after the high temperature process in the traditional method of forming films in the trench, so as to prevent the wafer from being seamed, warped, and bowed due to the thermal stress influence.

The present invention based on a general invention concept can be illustrated in at least two examples, including the method of forming films in the trench, and the method of manufacturing the power MOS device.

The improvements of the present invention include: 1) releasing the stress of the wafer to prevent the wafer from being seamed, wrapped, and bowed due to the thermal stress influence after the high temperature process, and 2) preventing the formation of voids in the trench.

The present invention will be illustrated in the following drawings and embodiments, but the processes, steps, materials, sizes, structures or other optional parts described in the embodiments do not limit the present invention; furthermore, the present invention is defined by the appended claims.

### BRIEF DESCRIPTION OF THE DRAWINGS

FIGS. 1(a)-(h) are flow diagrams showing the manufacturing process of a power MOS device according to an embodiment of the present invention, wherein FIGS. 1(a)-(d) show the method of forming films in the trench.

### DETAILED DESCRIPTION OF THE INVENTION

Some typical embodiments to present the features and advantages of the present invention will be particularly described in the following illustrations. It should be understood that the present invention may have various modifications in different modes, which are not apart from the scope of the present invention, and the illustrations and drawings of the present invention are substantially used for explaining but not for limiting the present invention.

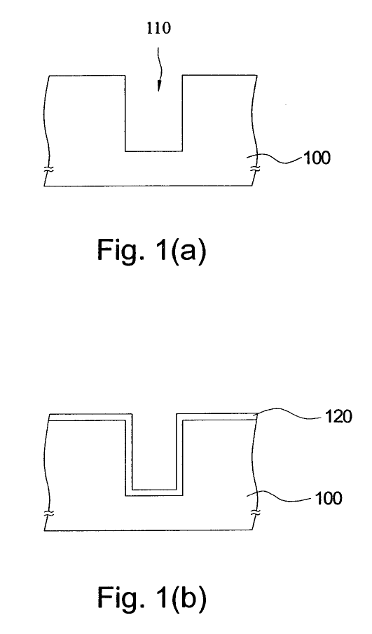

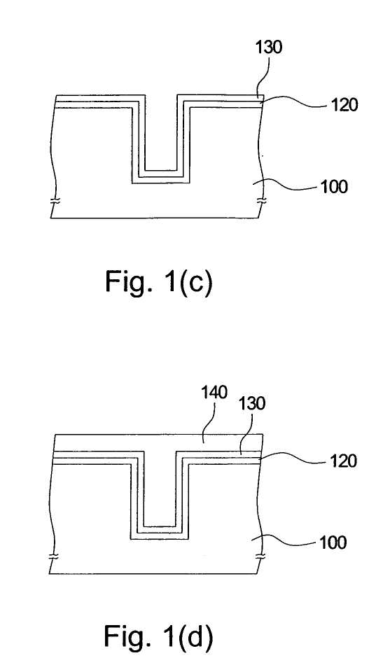

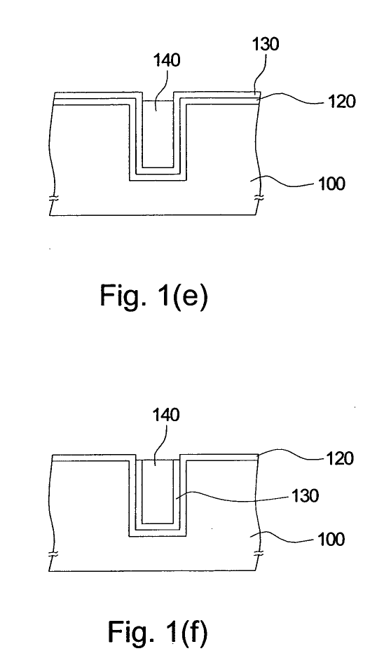

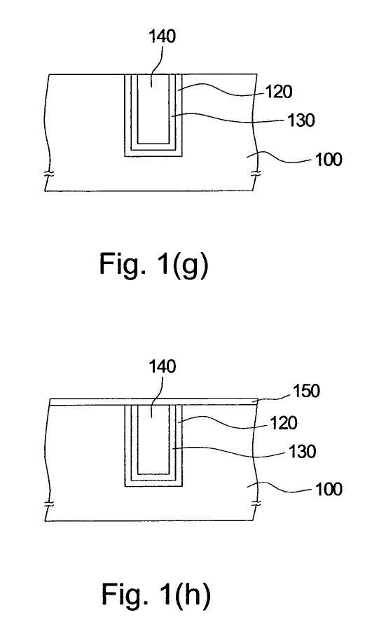

The method of forming films in the trench of the present embodiment is mainly applied to the manufacturing process of the trench-typed power MOS device to reduce or eliminate the thermal stress influence resulted from the different thermal expansion coefficients between different material layers after the high temperature process. FIGS. 1(a)-(h) are flow diagrams showing the manufacturing process of a power MOS device according to an embodiment of the present invention, wherein FIGS. 1(a)-(d) show the method of forming films in the trench of the present embodiment. As shown in FIG. 1(a), first, a semiconductor substrate 100 is provided. Next, a trench 110 is formed on the semiconductor substrate 100. In some embodiments, the aspect ratio of the trench 110 ranges from about 1 to 10.

Then, as shown in FIG. 1(b), a first dielectric layer 120 is formed on the semiconductor substrate 100 and the sidewalls of the trench 110. In some embodiments, the first dielectric layer 120 is an oxide layer, such as a silicon dioxide layer formed by thermal oxidation (or a silicon oxide layer formed by chemical vapor deposition).

With regard to the formation of the first dielectric layer, in some embodiments, the machine, TEL IW-6D, made by the Japanese company, TOKYO ELECTRON LIMITED can be used to perform a wet thermal oxidation process for forming the first dielectric layer, and the conditions, for example, are that: the operative temperature is 1050° C., the flow rates of H₂ and O₂ are respectively 5500 sccm and 3300 sccm, and the pressure is 760 torr, so that a part of the semiconductor substrate 100 can be oxidized into an oxide layer 120 with a thickness of about 2000 Å.

With regard to the formation of the first dielectric layer, in some embodiments, the machine, TEL IW-6D, made by the Japanese company, TOKYO ELECTRON LIMITED can be used to perform a dry thermal oxidation process for forming the first dielectric layer, and the conditions, for example, are that: the operative temperature is 1050° C., the flow rate of O₂ is 6000 sccm, and the pressure is 760 torr, so that a part of the semiconductor substrate 100 can be oxidized into an oxide layer 120 with a thickness of about 2000 Å.

With regard to the formation of the first dielectric layer, in some embodiments, the machine, TEL IW-6D, made by the Japanese company, TOKYO ELECTRON LIMITED can be used to perform a three-step thermal oxidation process for forming the first dielectric layer. The three-step thermal oxidation process includes dry-wet-dry thermal oxidation processes. The conditions of the first dry thermal oxidation process, for example, are that: the operative temperature is 1050° C., the flow rate of O₂ is 6000 sccm, and the pressure is 760 torr; the conditions of the following wet thermal oxidation process are that: the operative temperature is 1050° C., the flow rates of H₂ and O₂ are respectively 5500 sccm and 3300 sccm, and the pressure is 760 torr; the conditions of the second dry thermal oxidation process are the same as those of the first dry thermal oxidation process.

Later, as shown in FIG. 1(c), a second dielectric layer 130 is formed on the first dielectric layer 120, e.g., by chemical vapor deposition. In specific embodiments, the second dielectric layer 130 is silicon nitride. In some embodiments, the second dielectric layer 130 is formed by chemical vapor deposition with TEOS.

With regard to the formation of the second dielectric layer, in some embodiments, the machine, TEL IW-6C, made by the Japanese company, TOKYO ELECTRON LIMITED can be used to perform a chemical vapor deposition process, and the conditions, for example, are that: the operative temperature is between 750° C. and 800° C., the flow rates of NH₃ and SiH₂Cl₂ are respectively 400 sccm and 40 sccm, and the pressure is 0.3 torr, so that a silicon nitride layer 130 with a thickness of about 3000 Å is formed. Then, as shown in FIG. 1(d), a polysilicon layer 140 is formed in the trench 110, e.g., by chemical vapor deposition. In some embodiments, the machine, TEL IW-6C, made by the Japanese company, TOKYO ELECTRON LIMITED can be used to perform the chemical vapor deposition process twice, and the conditions, for example, are that: the operative temperature is 620° C., the flow rate of SiH₄ in the first tube is 90 sccm, the flow rate of SiH₄ in the second tube is 100 sccm, and the pressure is 0.25 torr, so that a polysilicon layer 140 with a thickness of about 7000 Å is formed.

After the above-mentioned process of forming films in the trench is finished, the following power MOS device manufacturing processes are performed. As shown in FIG. 1(e), a part of the polysilicon layer 140 outside the trench is removed after the process of forming films in the trench is finished. In some embodiments, the part of the polysilicon layer 140 is removed by chemical mechanical polish (CMP).

Next, as shown in FIG. 1(f), the second dielectric layer 130 outside the trench is removed. In some embodiments, the second dielectric layer 130 is removed by wet etching.

Then, as shown in FIG. 1(g), the first dielectric layer 120 outside the trench is removed. In some embodiments, the first dielectric layer 120 is removed by wet etching.

Later, as shown in FIG. 1(h), a gate oxide layer 150 is formed on the semiconductor substrate 100.

Finally, subsequent processes are performed to complete the manufacture of the power MOS device, which are known in the art.

As seen in FIGS. 1(a)-(d), the process of forming films in the trench of the present embodiment mainly takes advantage of the physical properties of various material layers. Through the compressive stress produced by the oxide layer 120 relative to the semiconductor substrate 100 after the high temperature process, the tensile stress produced by the silicon nitride layer 130 relative to the oxide layer 120 after the high temperature process, and the compressive stress produced by the polysilicon layer 140 relative to the silicon nitride layer 130 after the high temperature process, the thermal stress of the wafer can be moderated, so as to prevent the wafer from being seamed, warped, and bowed. Moreover, the formations of the oxide layer 120 and the silicon nitride layer 130 not only can cause the film thickness in the trench 110 to become even and uniform, but also prevent the formation of voids in the process of filling the polysilicon into the trench 110.

In conclusion, the method of forming films in the trench of the present embodiment takes advantage of the physical properties of various material layers to moderate the thermal stress of the wafer after the high temperature process, so as to further prevent the wafer from being seamed, warped, and bowed, and prevent the formation of voids in the trench.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A method of forming films in a trench for a manufacturing process of a power MOS device, the method comprising:
providing a semiconductor substrate;
forming a trench on said semiconductor substrate;
forming a first dielectric layer on sidewalls of said trench;
forming a second dielectric layer on said first dielectric layer; and
forming a polysilicon layer on said second dielectric layer in said trench.

2. The method of claim 1 wherein said first dielectric layer comprises an oxide.

3. The method of claim 2 wherein said oxide is silicon dioxide.

4. The method of claim 2 wherein said second dielectric layer comprises a nitride.

5. The method of claim 4 wherein said nitride is silicon nitride.

6. The method of claim 1 wherein said first dielectric layer is formed by thermal oxidation.

7. The method of claim 1 wherein said second dielectric layer is formed by chemical vapor deposition.

8. The method of claim 7 wherein said chemical vapor deposition is performed with TEOS.

9. The method of claim 1 wherein said polysilicon layer is formed by chemical vapor deposition.

10. The method of claim 1 wherein an aspect ratio of said trench ranges from about 1 to 10.

11. A method of manufacturing a power MOS device, comprising:
providing a semiconductor substrate;
forming a trench on said semiconductor substrate;
forming a first dielectric layer on sidewalls of said trench;
forming a second dielectric layer on said first dielectric layer; and
forming a polysilicon layer on said second dielectric layer in said trench.

12. The method of claim 11 wherein said first dielectric layer comprises an oxide.

13. The method of claim 12 wherein said oxide is silicon dioxide.

14. The method of claim 12 wherein said second dielectric layer comprises a nitride.

15. The method of claim 14 wherein said nitride is silicon nitride.

16. The method of claim 11 wherein said first dielectric layer is formed by thermal oxidation.

17. The method of claim 11 wherein said second dielectric layer is formed by chemical vapor deposition.

18. The method of claim 17 wherein said chemical vapor deposition is performed with TEOS.

19. The method of claim 11 wherein said polysilicon layer is formed by chemical vapor deposition.

20. The method of claim 11 wherein an aspect ratio of said trench ranges from about 1 to 10.

21. The method of claim 11 further comprising removing a part of said polysilicon layer disposed outside said trench.

22. The method of claim 21 wherein said part of said polysilicon layer is removed by chemical mechanical polish (CMP).

23. The method of claim 11 further comprising removing a part of said second dielectric layer disposed outside said trench.

24. The method of claim 23 wherein said second dielectric layer is removed by wet etching.

25. The method of claim 23 further comprising removing a part of said first dielectric layer disposed outside said trench.

26. The method of claim 25 wherein said first dielectric layer is removed by wet etching.
